(19) United States
(12) Patent Application Publication
(10) Pub. No.: US 2025/0208584 A1
(43) Pub. Date: Jun. 26, 2025

(54) WATCH COMPRISING A WIRELESS COMMUNICATION DEVICE

(71) Applicant: ETA SA MANUFACTURE HORLOGERE SUISSE, Grenchen (CH)

(72) Inventors: Dominique Dubugnon, Saint-Prex (CH); Pierpasquale Tortora, Neuchatel (CH); Sylvain Huot-Marchand, Eschert (CH); Raphael Courvoisier, Corcelles (CH)

(73) Assignee: ETA SA MANUFACTURE HORLOGERE SUISSE, Grenchen (CH)

(21) Appl. No.: 18/918,307

(22) Filed: Oct. 17, 2024

(30) Foreign Application Priority Data
Dec. 22, 2023 (EP) 23220046.9

(51) Int. Cl. G04G 17/04; G04G 21/04; G04R 60/06

(52) U.S. Cl. CPC G04G 17/04; G04G 21/04; G04R 60/06

(57) ABSTRACT

A dial (2a, 2b) of a watch (1) including a standalone wireless communication device (3), such a dial (2a, 2b) comprises visible and hidden faces (20a, 20b), said dial (2a, 2b) being formed by a stack (9a, 9b) of thin layers (10, 11, 12, 13, 14) of material extending between these two faces (20a, 20b), each of said layers (10, 11, 12, 13, 14) comprising one or more of the functional elements comprised in said device (3): a radio wave transceiver module (23); at least one light source (4); a standalone electric power supply unit (21), and a control unit (7) for managing the operation of said at least one light source (4) and of the transceiver module (23).

### CROSS REFERENCE TO RELATED APPLICATION

This application claims priority to European Patent Application No. 23220046.9 filed Dec. 22, 2023, the entire contents of which are incorporated herein by reference.

### TECHNICAL FIELD OF THE INVENTION

The present invention relates to a watch whose dial is equipped with a wireless communication device, said device being completely standalone.

### TECHNOLOGICAL BACKGROUND

In the prior art, electromechanical watches with hands are known in which the hour hand and the minute hand displaying the current time are driven by the trains of a horological movement mechanism. In this context, it might happen that, because of shocks subjected to the watch, the presence of electromagnetic fields or other external disturbances, the operation of the mechanism is disrupted. In order to limit, and even avoid, any damage to this mechanism, it is often necessary to identify at an early stage the disturbance(s) that may be the cause, as well as the malfunctions caused in the mechanism by these disturbances.

In this context, it should be understood that there is a need to find a solution that does not have the drawbacks of the prior art.

### SUMMARY OF THE INVENTION

The invention aims to overcome these drawbacks by providing a watch provided with a dial including a wireless communication device which is standalone and which helps warn the wearer of the watch about malfunctions detected in the latter.

One aspect of the invention relates to a watch dial comprising a standalone wireless communication device, such a dial comprises visible and hidden faces, said dial being formed by a stack of thin layers of material extending between these two faces, each of said layers comprising one or more of the functional elements comprised in said device:
a radio wave transceiver module;
at least one light source;
a standalone electric power supply unit, and
a control unit for managing the operation of said at least one light source and of the transceiver module.

In other embodiments:
the transceiver module operates according to the Bluetooth, WiFi and/or NFC technology;
the stack of thin layers of material comprises a first layer provided with the visible face of the dial and comprising said at least one transceiver module and said at least one light source;
said at least one transceiver module is arranged in a cavity formed in the hidden face of this dial;
said first layer is configured to be crossed in whole or in part by light radiation, in particular solar radiation;
said first layer is wholly or partly transparent or translucent;
the stack of thin layers of material includes a second layer comprising a photovoltaic module making up the standalone electric power supply unit;
the second layer comprises a substrate on which the photovoltaic module is printed;
said photovoltaic module is arranged on an active area of said second layer, said area being configured to receive light radiations originating from the first layer of the stack of thin layers of material;
the stack includes a third layer comprising an electrical energy accumulator making up the standalone electric power supply unit;
the third layer comprises a substrate on which the electrical energy accumulator is printed;
the stack includes a fourth layer forming a hidden face of the dial comprising the control unit;
the stack includes a third layer comprising a hidden face of the dial including the control unit and an electrical energy accumulator making up the standalone electric power supply unit;
the first layer is rigid compared to the other layers in the stack of thin layers of material, which are soft;
said visible and hidden sides are flat or domed.

Another aspect of the invention relates to a watch comprising such a dial.

Advantageously, the watch comprises a mechanical, electronic or electromechanical horological movement.

### BRIEF DESCRIPTION OF THE FIGURES

The aims, advantages and features of the invention will become clearer in the following description on the basis of at least one non-limiting embodiment illustrated by the drawings wherein:

FIG. 1 shows a perspective view of a watch comprising a dial provided with a wireless communication device which is standalone, according to embodiments of the invention;

FIG. 2 shows an exploded view of a first variant of the dial formed by a stack of four superimposed layers, each of said layers including one or more constituent element(s) of the wireless communication device, according to a first embodiment of the invention;

FIG. 3 shows a schematic view of this first variant of the dial provided with the wireless communication device, according to the first embodiment of the invention;

FIG. 4 shows an exploded view of a second variant of the dial formed by a stack of three superimposed layers, each of said layers including one or more constituent element(s) of the wireless communication device, according to a second embodiment of the invention, and

FIG. 5 shows a schematic view of this second variant of the dial provided with the wireless communication device, according to the second embodiment of the invention.

### DETAILED DESCRIPTION OF THE INVENTION

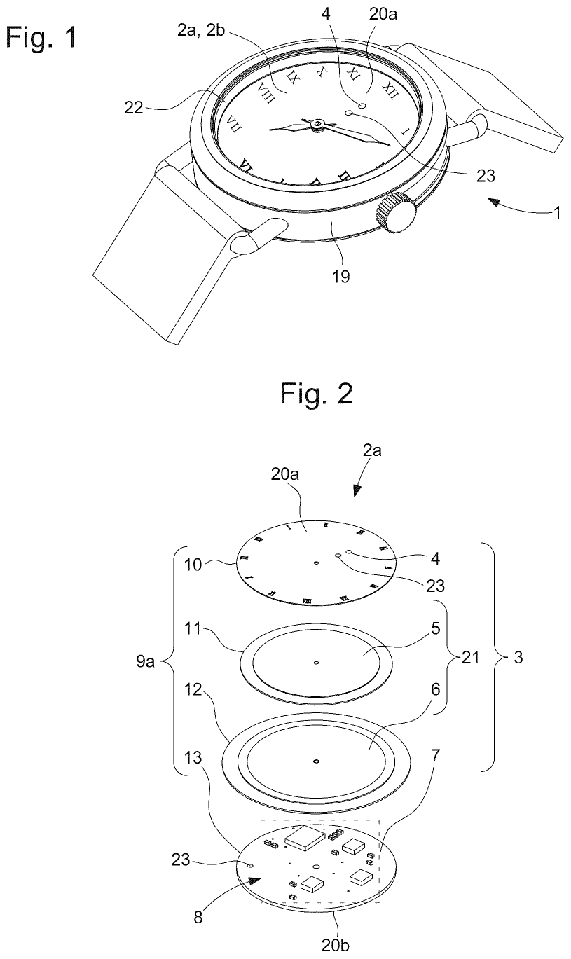

FIG. 1 illustrates a schematic representation of a watch 1 comprising a case 19 with a middle to which a back and a crystal 22 are attached, a set of components forming a horological movement, and a dial 2a, 2b arranged between the horological movement and the crystal 22.

In a manner known to a person skilled in the art, the horological movement drives a train comprising an hour hand, a minute hand and possibly a second hand. To this end, the dial 2a, 2b includes a through hole receiving the axis of the hands. This dial 2a, 2b also comprises two faces 20a, 20b including:
a so-called visible face 20a visible from the outside of the watch 1, also known as the “visible portion” or “visible upper portion” of this dial 2a, 2b, and
a so-called hidden face 20b arranged opposite the horological movement in an enclosure of the case 19 of the watch 1, this face 20b being otherwise so-called the “hidden portion” or “hidden lower portion” of this dial 2a, 2b.

Such a visible face 20a may comprise, in a non-limitative and non-exhaustive manner, at least one graphic representation such as:
a marker (or display) element like, for example, a digit, an index, a line or a dot contributing, with or without the hands, to the display of a horological information/measurement or a physical information/measurement measured by a sensor or the like comprised in the movement;
an inscription, pattern, text, logo, etc.

These visible 20a and hidden 20b faces are substantially flat and/or parallel and/or opposite each other. Note that, in other variants, the dial 2a, 2b may comprise a domed visible face 20a and a hidden face 20b which may be domed or flat. These faces 20a, 20b are also joined together by a peripheral wall of this dial 2a, 2b.

Moreover, it should be noted that in the embodiments illustrated in FIGS. 1 to 5, the dial 2a, 2b preferably has a circular shape. It should be understood that the invention can also be implemented for dials 2a, 2b having other shapes like, for example, a triangular shape or a quadrilateral-like shape.

In the embodiments of the invention, the horological movement is a mechanical movement. Alternatively, this movement may be an electromechanical or electronic movement. Hereafter, we will refer to a mechanical watch when its movement is mechanical, an electronic watch when it includes an electronic movement and an electromechanical watch when it includes an electromechanical movement.

With reference to FIGS. 2 and 4, such a dial 2a, 2b comprises a standalone wireless communication device 3. This communication device 3 comprises its own electric power supply means, as will be seen later on. Such a wireless communication device 3 is said to be standalone in particular with respect to the movement of the watch 1 and in particular with respect to the energy source of this movement, for example when this source is an electric power supply like in an electromechanical movement. Under these conditions, it should be understood that energy is not used by this wireless communication device 3 to the detriment of the autonomy of the movement.

In this context, the dial 2a, 2b can be removably mounted in the watch 1 regardless of the type of watch 1. The only condition to be met is that the dial 2a, 2b comprises this communication device 3, which is therefore standalone with respect to the movement of the watch 1. Note that this dial 2a, 2b is also called a “standalone dial” because it is not connected, in particular electrically, to the movement of the watch 1. This dial 2a, 2b may be considered as a part attached to the watch 1.

Such a communication device 3 enables this watch 1 to exchange data with an electronic device. These data may include information relating to functions implemented by the watch 1, like time functions, or functions implementing monitoring of events relating to the operation of the movement of this watch 1, such as an event relating to a water-resistance defect in the case 19 of this watch 1. Other examples of types of information that could be included in these data may include, but are not limited to, the following:
counting the number of passes made by at least one hand, if the watch 1 is so equipped, for example allowing determining the actual operating time of the watch 1, for example between two servicing or maintenance operations;
the number and nature (weak, strong) of shocks received by the case 19, when the dial 2a, 2b is provided with an accelerometer;
the number and intensity of exposures of the watch 1 to magnetic fields, when the dial 2a, 2b is provided with a magnetic sensor;
the internal pressure and/or humidity of the case 19, which could indicate a loss of water-resistance of the watch 1, when the dial is provided with a pressure and/or humidity sensor;
the orientation of the watch 1, and the duration of these orientations, when the dial 2a, 2b is equipped with a gyroscope, in order, for example, to improve the adjustment of the watch according to its wearer, or to adapt the frequency of the maintenance services necessary for the proper operation of the watch 1, this may form part of predictive maintenance;
the detection of an abnormal operating noise when the dial 2a, 2b is equipped with an acoustic sensor, allowing predicting or signaling a fault/dysfunction.

Hence, it should be understood that, in this context, the communication device 3 may comprise, in a non-limiting and non-exhaustive manner, the following event sensors:
needle positioning sensor;
accelerometer sensor;
pressure sensor;
humidity sensor;
angular position sensor;
gyroscopic and/or inertial sensor in the form of an electronic component of the gyroscopic and/or inertial electromechanical microsystem circuit type;
acoustic sensor.

It should be noted that the aforementioned electronic device is preferably a mobile device, i.e. one that is likely to be worn and carried by a user, and also to be functional while being carried. For example, it could be a smartphone or a tablet. Alternatively, this electronic device may be a computer, in particular a laptop. In this context, this device comprises a communication unit compatible with a transceiver module 23 of the communication device 3 of the dial 2a, 2b of the watch 1.

This communication device 3 comprised in this dial 2a, 2b, includes at least one light source 4 also called light source, a standalone electric power supply unit 21, the transceiver module 23, and a control unit 7.

In this device 3, said at least one light source 4 is implemented in particular to contribute to displaying the different operating parameters of the communication device 3, like for example:
the establishment of a connection with said electronic device;
the connection type: Bluetooth, WiFi, etc;
the network traffic present on the connection established between the watch and the device;
the bandwidth of the connection established between the watch and the device;
the start or end of data transmission/download between the watch and the device;
etc.

In this communication device 3, each light source 4 may correspond to any electroluminescent element selected from a non-exhaustive and non-limiting list comprising:
an electroluminescent capacitor known by the acronym LEC standing for “Light-Emitting Capacitor”;
a light-emitting diode such as LED (acronym for “Light-Emitting Diode”), OLED (acronym for “Organic Light-Emitting Diode”), AMOLED (acronym for “Active-Matrix Organic Light-Emitting Diode”) or QLED (acronym for “Quantum Light-emitting diode”);
any electroluminescent material activated by a local electric field;
any electroluminescent material activated by an electric current;
any combination of these electroluminescent elements.

It should be noted that this light source 4 may, in some embodiments of the invention, be a light source 4 capable of forming an extended light source. This allows conferring a predetermined shape on the extended light source, typically, without this being exhaustive or limiting, a shape relating to a graphic representation relating to an operating parameter of the communication device 3 such as a digit, a letter, a logo or a text. It should also be noted that this light source 4 can produce light in any colour and/or in any direction.

In this communication device 3, said transceiver module 23 is configured to enable bidirectional communication in radio space between the watch and the electronic device. This communication may be half-duplex, when the watch and the electronic device can both receive and send data, the transmission can take place between the communicating parties one after another. This communication may also be full-duplex, when the watch 1 and the electronic device can send and receive messages simultaneously.

Such a transceiver module 23 implements wireless communication technologies such as Bluetooth, Wi-Fi, Li-Fi (abbreviation of Light Fidelity), WiMAX, the communication technology relating to a mobile telephony network standard, the communication technology relating to a satellite network standard. Furthermore, this transceiver module 23 is able to implement a combination of at least two of these aforementioned technologies.

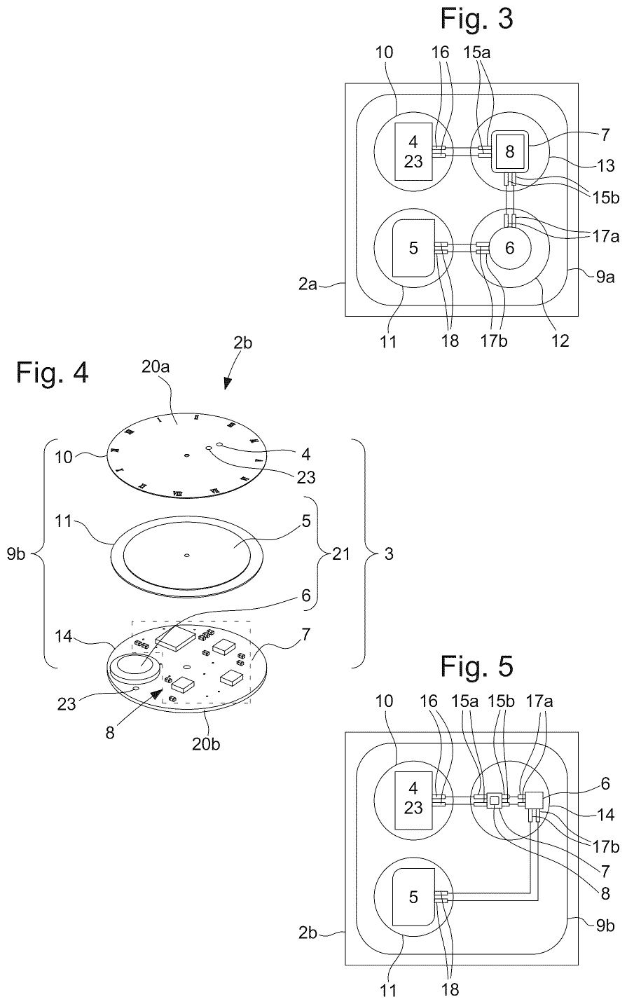

In this communication device 3, the standalone electric power supply unit 21 includes an electrical energy accumulator 6 and a photovoltaic module 5 comprising at least one photovoltaic cell, also known as a solar cell. This photovoltaic module 5 is connected to the electrical energy accumulator 6 via connection elements referenced 17b and 18 in FIGS. 3 and 5. This photovoltaic module 5 may comprise one or more elementary cell(s) of the heterojunction or multijunction type, connected in parallel or in series. Each photovoltaic cell of this module 5 may be made, in a manner known to a person skilled in the art, from semiconductor materials based on copper, indium, gallium and selenium, based on cadmium telluride, based on monocrystalline gallium arsenide or based on monocrystalline or polycrystalline silicon, or with perovskites. It should be noted that these examples are not limitative and that a person skilled in the art will be able to find the type of photovoltaic cell suitable for the invention.

In this communication device 3, the control unit 7, also known as a microcontroller, includes an electronic circuit 8 comprising hardware resources, in particular at least one processor cooperating with memory elements as well as address, data and control buses. This control unit 7 is connected to said at least one light source 4, to the transceiver module 23 and to the standalone electric power supply unit 21. Such a control unit 7 comprises in its memory elements 4 an algorithm for managing the data exchanged between the watch 1 and the electronic device.

Moreover, in the case where the communication device 3 comprises several light sources 4, their operation can then be managed/controlled by the control unit 7 simultaneously and/or in sequence. In addition, each light source 4 is managed/controlled by this control unit 7 separately. In this context, the management of the operation of each light source 4 may consist of, but is not limited to, the following operations: a sequential switching on or off, simultaneous switching on or off of two or more light sources 4, a blinking of one or more light sources 4, a definition of a blinking frequency for each light source 4, a blinking duration for each light source 4, a switching on or off duration for each light source 4, etc.

Such a control unit 7 may also comprise in its memory elements an algorithm for managing the electrical energy accumulator 6, in particular for managing recharging thereof by the photovoltaic module 5 and for managing the electrical consumption by said light source 4 and/or the transceiver module 23.

As mentioned above, the standalone communication device 3 is therefore comprised in the dial 2a, 2b. In this configuration, the constituent elements of this communication device 3, namely the light source 4, the electrical energy accumulator 6, the photovoltaic module 5, the transceiver module 23 and the control unit 7, are comprised in one or more layer(s) 10, 11, 12, 13, 14 forming this dial 2a, 2b.

With reference to FIGS. 2 to 5, this dial 2a, 2b consists of a stack 9a, 9b of a plurality of thin/fine layers 10, 11, 12, 13, 14, these layers 10, 11, 12, 13, 14 are joined together by a joining element such as an adhesive substance so as to unify them in order to obtain a stack 9a, 9b of monolithic thin layers thus forming a one-piece dial 2a, 2b. This joining element may also be a clip or a screw. Such layers 10, 11, 12, 13, 14 are superimposed in the stack 9a, 9b of layers, i.e. they are arranged on top of one another in this dial 2a, 2b in a defined order. Note that such a stack 9a, 9b of layers may also be called an assembly of layers. In this stack 9a, 9b, the layers are substantially similar, having upper and lower surfaces with substantially the same area/surface, thereby contributing to forming the peripheral wall of the dial 2a, 2b, which has no relief.

It should be noted that these thin or fine layers are layers each having a micrometric thickness. Indeed, each layer may have a thickness comprised between 1 and 100 μm, preferably 2 μm, or preferably 3 μm. As regards to the thickness of the dial 2a, 2b, it may be between 8 and 400 μm, preferably 6 μm or preferably 12 μm or preferably 100 μm or preferably 200 μm or preferably 300 μm.

Thus, such a one-piece dial 2a, 2b has the additional advantage of being removably mounted in the case 19 of the watch 1, as well as facilitating integration thereof into this case 19.

In a first variant of this stack 9a of layers illustrated in FIG. 3, the latter consists of four successive thin/fine layers 10, 11, 12, 13 as follows:
a first layer 10 forming/making up the visible face 20a of the dial 2a including the transceiver module 23 and/or said at least one light source 4;
a second layer 11 including the photovoltaic module 5;
a third layer 12 including an electrical energy accumulator 6, also known as a rechargeable battery, and
a fourth layer 13 forming the hidden face 20b of the dial 2a including the transceiver module 23 and/or the control unit 7.

The first layer 10 of this stack 9a is preferably rigid or semi-rigid in comparison with the second, third and fourth thin/fine layers 11, 12, 13 which are preferably soft or flexible. It should be understood herein that such a first layer 10 contributes to structurally stiffening the stack 9a of thin layers and therefore the dial 2a.

In this stack 9a, each of the first, second, third and fourth layers 10, 11, 12 and 13 comprises an upper surface and a lower surface.

As regards the first layer 10, it is formed by a transparent or translucent or at least partially transparent or at least partially translucent rigid or semi-rigid substrate. Such a substrate is made of a material with a transmittance to solar radiations, in particular ultraviolet radiations, also known as UVT (for “Ultra-Violet Transmission”) which is comprised between 65 and 95 percent. This transmittance is preferably 85 percent. Such a material may be transparent or translucent. This material may be, but is not limited to, a polymer, glass or ceramic.

In this context, it should be understood that this substrate is configured so that:
the light produced by said at least one light source could escape to the outside of the dial 2a, 2b and therefore of the watch 1, and
the light originating from the environment of the watch 1 could penetrate the dial 2a, 2b in the direction of the photovoltaic module 5 of the communication device 3, this light comprising solar radiation when it is of natural origin.

In other words, this transparent or translucent substrate is configured to be penetrated by this light likely to supply the photovoltaic module 5 so that the latter could convert the solar energy from this radiation into electrical energy.

This first layer 10 also comprises at least one light source 4 which is arranged in the body of the substrate. Such an arrangement of the light source 4 in this substrate is configured to ensure illumination of all or part of the visible face 20a of the dial 2a. For example, illumination of a graphic representation relating to an operating parameter of the communication device 3, such as a marker element (or display) like a digit, an index, a line, a dot or illumination of one or more hand(s), or illumination of all or part of the surface of the visible face of the dial 2a. In one variant, this light source 4 may have a predetermined shape such as the shape of a digit, a letter, an index, a line, a dot, a logo or a text.

This lighting may be backlighting or semi-direct lighting when the light source 4 is arranged in a cavity defined in the substrate. More specifically, this cavity may be a blind opening made in the lower surface of this substrate. In this configuration, when the bottom of this cavity comprises a graphic representation relating to an operating parameter of the communication device 3, the light radiation, or the light, produced by this light source 4 can escape to the outside of the dial 2a via the visible face 20a of this dial 2a, thereby enabling at least one graphic representation to be viewed in the dark. In particular, the light radiation escaping from the visible face 20a draws the outline of this graphic representation. In this context, this graphic representation comprised in or on the upper surface or on the lower surface of the substrate forming the first layer 10, is preferably opaque or non-translucent or non-transparent.

This lighting may be direct lighting when the light source 4 is arranged in a cavity defined in the substrate. This cavity may be a blind opening made in the lower surface of this substrate, the bottom of which is devoid of any graphic representation. In this configuration, the luminous radiation, or light, produced by this light source 4 can escape through the bottom of this cavity towards the outside of the dial 2a and therefore through the visible face 20a of this dial 2a.

This lighting may also be direct lighting when the light source 4 is arranged in a through opening extending across the thickness of the substrate of the first layer 10, opening out at its two ends respectively in the upper and lower surfaces of this substrate. In this configuration, all or part of the light source 4 may project from the upper surface of this substrate and therefore from the first layer 10 or from the visible face 20a of the dial 2a to form a graphic representation relating in particular to an operating parameter of the communication device 3, such as an index, a digit, a dot, a line, etc.

Such lighting may also be remote lighting when said at least one light source 4 is coupled to at least one waveguide. This waveguide, also known as a light guide, allows carrying the light from the point where it is injected into the guide up to the substrate or up to an area of the substrate (e.g. cavity, through opening) close to the upper surface of this substrate. Such a light guide may be an optical fibre which allows circumventing any obstacles that may arise in the substrate, for example between the electroluminescent element and the area of the substrate close to the upper surface of the substrate, through which the light will escape. In this variant, it is therefore the light which is brought, via the waveguide, from the electroluminescent element up to this area of the substrate to be illuminated.

In such a configuration, a first end of the waveguide is coupled to the light source 4 and a second end of the waveguide may be arranged in:
a cavity which may be a blind opening made in the lower surface of the substrate of this first layer 10, or
a through opening extending through the thickness of the substrate of the first layer 10 and opening at its two ends respectively into the upper and lower surfaces of this substrate and therefore of the first layer 10. Thus, this second end may project from the upper surface of the substrate or of this first layer 10 or from the visible face 20a of the dial 2a in order, for example, to form a graphic representation relating in particular to an operating parameter of the communication device 3, like for example a marker element such as an index, a digit, a dot, a line, etc.

In this context, indirect lighting may be achieved by one single light source 4 comprised on the lower surface of the substrate of this first layer 10 and coupled to several waveguides, the second ends of which are arranged in:
cavities each emitting a light radiation originating from this light source 4, this radiation escaping to the outside of the dial 2a via the visible face 20a, thus enabling at least one graphic representation to be viewed in the dark. In this context, this graphic representation comprised in or on the visible face 20a of the dial 2a, or the upper surface of the substrate, is preferably opaque, and/or
through openings projecting, or not, from the upper surface of this substrate in order to form marker elements such as an index, a line or a dot, and each emitting a light radiation originating from this light source 4.

In this first layer 10, the light source 4 or the transceiver module 23 is applied/fixed to the lower surface of this substrate of this first layer 10, in a cavity or on an inner wall of a previously mentioned through opening, by printing or evaporation.

In this first layer 10, the transceiver module 23 is arranged in/on this substrate in order to be able to pick up the radio waves. This transceiver module 23 may be arranged on or under the upper surface of this substrate forming the first layer 10. When arranged in the substrate, this transceiver module 23 is positioned in a blind cavity formed in this upper surface. In one variant, it may be arranged in a blind cavity made in the lower surface of this substrate having this upper surface as its bottom. In this configuration, the radio waves propagating in the dial 2a, 2b and in the visible face 20a can be picked up by said transceiver module 23. This substrate may also comprise a through opening connecting the upper and lower surfaces together and in which the transceiver module 23 may be arranged.

Furthermore, it should be noted that the lower surface of this first layer 10 may be self-adhesive so that it contributes to assembly thereof with the second layer 11.

In this stack 9a, the second layer 11 comprises a substrate including the photovoltaic module 5. Such a substrate is preferably flexible or soft. The substrate of the second layer 11 may be a film on which the photovoltaic module 5 is arranged. Finally, this substrate may be made of a material belonging to the polymer family.

In this second layer 11, the photovoltaic module 5 preferably extends over the entirety of a so-called active area of the upper surface of this substrate. This active area is a portion of the upper surface of the substrate which is able to receive light originating from the lower surface of the first layer 10 of the dial 2a. This light, which has passed through all or part of the first layer 10, originates from the external environment of the dial 2a, and therefore of the watch 1, in this case mainly from solar radiation when it is of natural origin.

It should be noted that the photovoltaic module 5 is applied to the upper surface of this substrate using inkjet printing or screen-printing processes or using thermal evaporation printing processes. We will refer herein to a second layer 11 comprising a printed photovoltaic module 5. In particular, a photovoltaic module 5 printed on the substrate of the second layer 11.

It will be noted that once the photovoltaic module 5 has been applied to the substrate, a layer of a self-adhesive substance may be deposited over all or part of the upper surface and/or the lower surface of the substrate. Under these conditions, the second layer 11 may be a self-adhesive layer which contributes to facilitating assembly thereof with the other layers, in particular with the first layer 10 and/or the third layer 12 of this stack 9a.

In the stack 9a, this third layer 12 also comprises a preferably flexible or soft substrate, including the electrical energy accumulator 6 of the standalone communication device 3. This substrate of the third layer 12 may be a film on which the accumulator 6 is comprised. Such a substrate may be made of a material belonging to the polymer family.

This accumulator 6 may be a lithium battery or a semiconductor battery. Such an accumulator 6 is applied to the upper surface of this substrate using processes known in the state of the art, such as:
printing processes on a flexible polymer substrate, for example a lithium battery, or
three-dimensional printing processes, for example for a semi-conductor battery such as a lithium-metal semiconductor battery.

We will refer herein to a third layer 12 comprising a printed electrical energy accumulator 6. In particular, an electrical energy accumulator 6 printed on the substrate of the third layer 12.

Thus, such processes allow obtaining a third layer 12 comprising this accumulator 6 which is soft and ultra-fine.

Furthermore, it should be noted that once the accumulator 6 has been applied to the substrate, a layer of a self-adhesive substance can be deposited over all or part of the upper surface and/or of the lower surface of this substrate. Under these conditions, the third layer 12 may be a self-adhesive layer which contributes to facilitating assembly thereof with the other layers, in particular with the second layer 11 and/or the fourth layer 13 of this stack 9a.

Note that this accumulator 6 is used to store the electrical energy produced by the photovoltaic module 5 and to release it on demand to power the communication device 3, said at least one light source 4 and the transceiver module 23.

In this stack 9a, this fourth and last layer 13 forms the hidden face of the dial 2a. This fourth layer 13 is formed by a preferably flexible or soft substrate including the control unit 7. Such a substrate for the fourth layer 13 may, for example, be a flexible PCB on which this control unit 7 is arranged, in particular on the upper surface of this PCB and therefore of the substrate. In this context, the construction of the control unit 7, and of the transceiver module where applicable, on this upper surface of the substrate may be carried out using three-dimensional printing processes or polymer printing processes.

In this last and fourth layer 13, the transceiver module 23 is arranged in/on this substrate in order to be able to pick up the radio waves. This transceiver module 23 may be arranged on or under the lower surface of this substrate forming this fourth layer 13. When arranged in the substrate, this transceiver module 23 is positioned in a blind cavity formed in this lower surface. In one variant, it may be arranged in a blind cavity made in the upper surface of this substrate having this lower surface as its bottom. In this configuration, the radio waves propagating in the dial 2a, 2b and in the hidden face 20b can be picked up by said transceiver module 23. This substrate may also comprise a through opening connecting the upper and lower surfaces together and in which the transceiver module 23 may be arranged.

In the second variant, the stack 9b forming the dial 2b comprises three thin/fine layers 10, 11, 14, joined together. Note that this second variant differs from the first variant in that it therefore comprises three layers 10, 11, 14 instead of four layers 10, 11, 12, 13, like in the first variant. In this second variant, the electrical energy accumulator 6 of the communication device 3 is now comprised in the third and last layer 14 of this stack 9b with the control unit 7.

Such a third and last layer 14 of this stack 9b, forming the hidden face of the dial 2b, consists of a preferably flexible or soft substrate, on which are built, preferably on the upper surface of this substrate, the battery 6 and the electronic circuit 8 making up the control unit 7. Such a construction of the battery 6 and of the control unit 7 on this upper surface of the substrate may be carried out using three-dimensional printing processes or polymer printing processes. It should be noted that such a substrate may be, for example, a flexible PCB.

In this last and third layer 14 of this second variant, the transceiver module 23 is arranged in/on this substrate in order to be able to pick up the radio waves. This transceiver module 23 may be arranged on or under the lower surface of this substrate forming the third layer 14. When arranged in the substrate, this transceiver module 23 is positioned in a blind cavity formed in this lower surface. In one variant, it may be arranged in a blind cavity made in the upper surface of this substrate having this lower surface as its bottom. In this configuration, the radio waves propagating in the dial 2a, 2b and in the hidden face 20b can be picked up by the transceiver module 23. This substrate may also comprise a through opening connecting the upper and lower surfaces together and in which the transceiver module 23 may be arranged.

In summary, in this second variant, the stack 9b comprises:
a first layer 10 forming the visible face 20a of the dial 2b including the transceiver module 23 and/or said at least one light source 4;
a second layer 11 including the photovoltaic module 5, and
the third layer 14 forming the hidden face 20b of the dial 2b including the transceiver module 23 and/or the accumulator 6 and the control unit 7.

Note that in this second variant, the first and second layers 10, 11 are similar to those of the first variant of stack 9a.

Moreover, with reference to FIGS. 3 and 5, the electronic circuit 8 of the control unit 7 comprises first connection elements 15a which are connected to connection elements 16:
of said at least one light source 4 for managing the operation of this light source 4 for displaying the different operating parameters of the communication device 3, and
of the transceiver module 23 for participating in the management of data exchanges between the watch and the electronic device.

This electronic circuit 8 also comprises second connection elements 15b connected to first connection elements 17a of the accumulator 6.

In a third variant not shown, the stack of thin/fine layers forming the dial comprises two interconnected layers. Note that this third variant differs from the second variant in that it comprises two layers instead of three layers 10, 11, 14, like in this second variant. In this third variant, the photovoltaic module 5 of the standalone communication device 3 is now comprised in the first layer and in particular on the lower surface of the substrate forming this first layer. This photovoltaic module 5 may be applied to this lower surface of the substrate of this first layer using inkjet printing or screen-printing processes or using thermal evaporation printing processes. It should therefore be noted that this first layer is then similar to the first layers 11 of the first and second variants, with the exception that in this third variant, the first layer additionally comprises the photovoltaic module.

Moreover, in the third variant, and similarly to the second variant, the electrical energy accumulator 6 of the standalone communication device 3 is comprised in the second and last layer of this stack with the control unit 7. Such a second layer, forming the hidden face of the dial, consists of a preferably flexible or soft substrate, on which are built, preferably on the upper surface of this substrate, the battery 6 and the electronic circuit 8 making up the control unit 7. This construction of the battery 6 and of the control unit 7 on the upper surface of the substrate may be carried out using three-dimensional printing processes or polymer printing processes. It should be noted that such a substrate may be a flexible PCB, for example.

In the last layers 13, 14 of the different variants, the transceiver module 23 is applied/fixed to the lower or upper surface of the substrate of these layers, in a cavity or on an inner wall of a through opening mentioned above, by printing or evaporation.

In summary, in this third variant, the stack of layers then comprises:
a first layer forming the visible face 20a of the dial including the transceiver module 23 and/or said at least one light source 4 and the photovoltaic module 5, and
a second layer forming the hidden face 20b of the dial including the transceiver module 23 and/or the accumulator 6 and the control unit 7.

Furthermore, it should be noted that the above-mentioned event sensors of the communication device 3 are preferably arranged in the first layer 10 and/or the last layer 13, 14 of the stack of layers 9a, 9b and are connected to the control unit 7 of this device 3.

It goes without saying that the present invention is not limited to the embodiments just described and that various simple modifications and variants may be considered by a person skilled in the art without departing from the scope of the invention as defined by the appended claims.

1. A dial for a watch comprising an standalone wireless communication device, such a dial comprises visible and hidden faces, said dial being formed by a stack of thin layers of material extending between these two faces, each of said layers comprising one or more of the functional elements comprised in said device:
a radio wave transceiver module;
at least one light source;
a standalone electric power supply unit; and
a control unit for managing the operation of said at least one light source and of the transceiver module.

2. The dial according to claim 1, wherein the transceiver module operates according to a Bluetooth, WiFi and/or NFC technology.

3. The dial according to claim 1, wherein the stack of thin layers of material comprises a first layer provided with the visible face of the dial and the first layer comprising said at least one transceiver module and said at least one light source.

4. The dial according to claim 1, wherein said at least one transceiver module is arranged in a cavity formed in the hidden face of this dial.

5. The dial according to claim 1, wherein said first layer is configured to be crossed in whole or in part by light radiation, in particular solar radiation.

6. The dial according to claim 1, wherein said first layer is wholly or partly transparent or translucent.

7. The dial according to claim 1, wherein the stack of thin layers of material includes a second layer comprising a photovoltaic module making up the standalone electric power supply unit.

8. The dial according to claim 1, wherein the second layer comprises a substrate on which the photovoltaic module is printed.

9. The dial according to claim 1, wherein the stack of thin layers of material includes a second layer comprising a photovoltaic module making up the standalone electric power supply unit, the said photovoltaic module being arranged on an active area of said second layer, said area being configured to receive light radiations originating from the first layer of the stack of thin layers of material.

10. The dial according to claim 1, wherein the stack includes a third layer comprising an electrical energy accumulator making up the standalone electric power supply unit.

11. The dial according to claim 1, wherein the stack includes a third layer comprising an electrical energy accumulator making up the standalone electric power supply unit, the third layer comprising a substrate on which the electrical energy accumulator is printed.

12. The dial according to claim 1, wherein the stack includes a fourth layer forming a hidden face of the dial comprising the control unit.

13. The dial according to claim 1, wherein the stack includes a third layer comprising a hidden face of the dial including the control unit and an electrical energy accumulator making up the standalone electric power supply unit.

14. The dial according to claim 1, wherein the first layer is rigid compared to the other layers comprised in the stack of thin layers of material which are soft.

15. The dial according to claim 1, wherein said visible and hidden faces are flat or domed.

16. A watch comprising the dial according to claim 1.

17. The watch according to claim 16, comprising a mechanical, electronic or electromechanical horological movement.
